(19) United States
(12) Patent Application Publication
(10) Pub. No.: US 2007/0262402 A1
(43) Pub. Date: Nov. 15, 2007

(54) INTEGRATED INDUCTOR WITH HIGHER MOMENT MAGNETIC VIA

(76) Inventor: Chang-Min Park, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/382,839

(22) Filed: May 11, 2006

(51) Int. Cl. B32B 15/04; H01L 29/82; H01L 21/00; H01L 43/00

(52) U.S. Cl. 257/423; 428/693.1; 438/73

(57) ABSTRACT

Embodiments of the invention provide an inductor integrated on a microelectronic die. The inductor may include upper and lower layers of magnetic material above and below an electrically conductive coil. There may be a magnetic via between the upper and lower layers of magnetic material. The magnetic via may comprise a material with a higher saturation flux density than the material of which the upper and lower layers of magnetic material are comprised.

### BACKGROUND

### Background of the Invention

High performance electronics make use of voltage regulators. As processor technology scales to smaller dimensions, supply voltages to circuits within a processor will also scale to smaller values. The power consumption of processors has also been increasing. Using an external power supply or an off-chip voltage regulator to provide a small supply voltage to a processor with a large power consumption will lead to a larger total electrical current being supplied to the processor. Further, there has been interest in using two different voltage supplies for dies that include more than one microprocessor. This allows each processor on the die to be supplied with power individually, cutting the overall power usage and heat production. Using one or more off-chip voltage regulators to provide two circuit supply voltages to a processor die can lead to an increase in complexity, pin count, and cost. On-die integrated voltage regulators can reduce complexity and cost and improve performance.

### BRIEF DESCRIPTION OF THE DRAWINGS

FIGS. 1a and 1b are cross sectional side views of a device according to one embodiment of the present invention.

FIGS. 1c and 1d are top views that further illustrates the inductor of FIGS. 1a and 1b.

FIG. 2 is a cross sectional side view that that illustrates an embodiment with the device layer on the substrate layer and the interconnect/ILD layers on the device layer.

FIG. 3 is a cross sectional side view that that illustrates a blanket magnetic layer formed on the interconnect/ILD layers.

FIG. 4 is a cross sectional side view that illustrates the lower magnetic layer formed by patterning the blanket magnetic layer.

FIG. 5 is a cross sectional side view that illustrates a first dielectric layer formed over the patterned lower magnetic layer.

FIGS. 6a and 6b are a cross sectional view and a top view illustrating the coil formed on the first dielectric layer.

FIG. 7 is a cross sectional side view that that illustrates a second dielectric layer formed over the coil.

FIG. 8 is a cross sectional side view that that illustrates a blanket magnetic layer formed on the second dielectric layer.

FIG. 9 is a cross sectional side view that illustrates a trench formed through the magnetic layer and dielectric layers to the lower magnetic layer.

FIG. 10 is a cross sectional side view that that illustrates the magnetic via formed in the trench.

FIG. 11 is a cross sectional side view of another embodiment of the device of FIG. 1.

FIG. 12 is a cross sectional side view of yet another embodiment of the device.

FIG. 13 illustrates a system in accordance with one embodiment of the present invention.

### DETAILED DESCRIPTION

In various embodiments, an apparatus and method relating to the formation of an inductor with a coil between upper and lower magnetic layers, and a magnetic via with a higher moment magnetic via than the upper and lower magnetic layers are described. In the following description, various embodiments will be described. However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

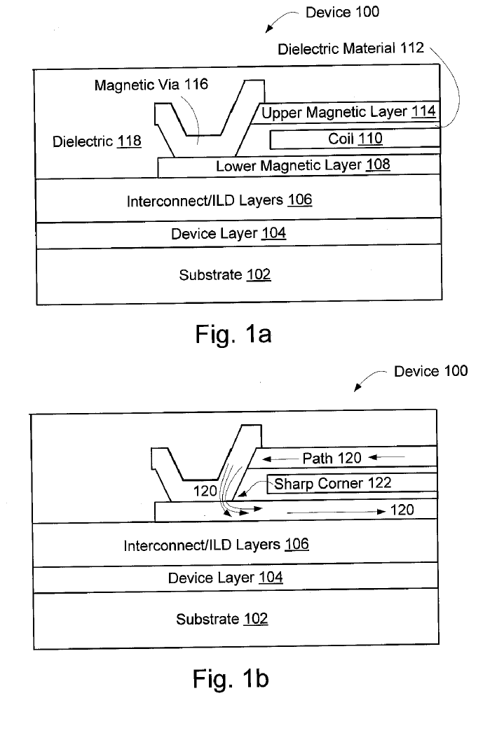

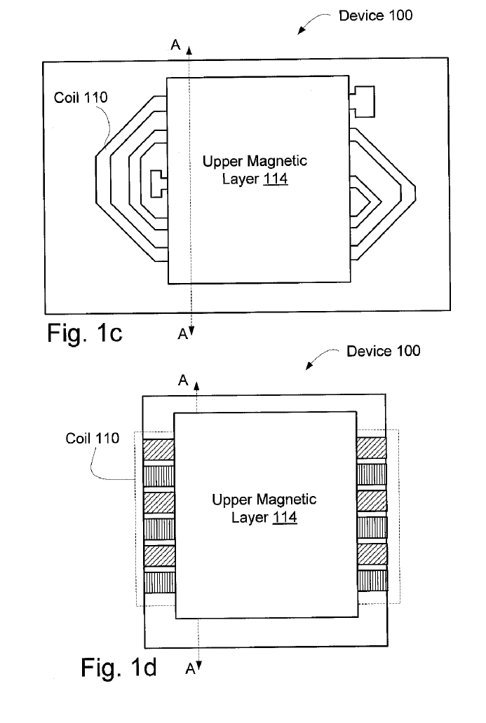

FIGS. 1a and 1b is a cross sectional side view that illustrates a device 100 with an inductor with a coil between upper and lower magnetic layers, and a magnetic via with a higher moment magnetic via than the upper and lower magnetic layers, according to one embodiment of the present invention. The device 100 may be a microprocessor die, another type of die, a wafer with multiple dies, or another type of device 100.

The device 100 may include a substrate 102. The substrate 102 may comprise any material that may serve as a foundation upon which a semiconductor device may be built. In this embodiment, substrate 102 is a silicon containing substrate. The substrate 102 may be a bulk substrate 102, such as a wafer of single crystal silicon, a silicon-on-insulator (SOI) substrate 102, such as a layer of silicon on a layer of insulating material on another layer of silicon, or another type of substrate 102.

There may be a device layer 104 on the substrate 102. The device layer 104 may include one or more transistors and/or other types of devices. In an embodiment, the device layer 104 includes transistors and other devices that, together, form a microprocessor. In an embodiment, the device layer 104 includes devices that together form multiple microprocessor cores on a single die.

There may be interconnect and interlayer dielectric (ILD) layers 106 on the device layer 104. These layers 106 may provide conductive vias and traces to electrically interconnect devices of the device layer 104 to each other and to other components, on and off die. The ILD layers 106 may separate and insulate the vias and traces. There may be several layers each of vias and traces and ILD in the interconnect and ILD layers 106.

There may be a lower magnetic layer 108 and an upper magnetic layer 114. The upper and lower magnetic layers 114, 108 may each comprise a magnetic material such as Ni₈₀Fe₂₀, CoZrTa, Ni₄₅Fe₅₅, or another magnetic material. The upper and lower magnetic layers 114, 108 may comprise the same or different materials. In some embodiments, the saturation flux density of the material of the upper and lower magnetic layers 114, 108 may be between about 1.0 and about 1.7 Tesla.

Between the upper and lower magnetic layers 114, 108 may be an electrically conductive coil 110. The coil 110 may comprise any suitable conductive material, such as copper, aluminum, or another material. The coil 110 may be insulated from the upper and lower magnetic layers 114, 108 by dielectric material 112.

There may be a magnetic via 116 between the upper and lower magnetic layers 114, 108. “Between” as used herein does not necessarily mean physically between the upper and lower magnetic layers 114, 108. For example, as seen in FIG. 1a, the magnetic via 116 is above the lower magnetic layer 108, but next to and above the upper magnetic layer 114. Rather, the magnetic via 116 is part of at least a portion of the path the magnetic flux travels between the upper and lower magnetic layers 114, 108, as is further illustrated in FIG. 1b.

In an embodiment, the magnetic via 116 comprises a magnetic material with a higher saturation flux density than the material(s) of the upper and lower magnetic layers 114, 108. In an embodiment, the magnetic via 116 comprises a material with a saturation flux density at least 20% higher than the material(s) of the upper and lower magnetic layers 114, 108. In another embodiment, the magnetic via 116 comprises a material with a saturation flux density at least 30% higher than the material(s) of the upper and lower magnetic layers 114, 108. In another embodiment, the magnetic via 116 comprises a material with a saturation flux density at least 50% higher than the material(s) of the upper and lower magnetic layers 114, 108. In an embodiment, the magnetic via 116 comprises a material with a saturation flux density of at least about 1.8 Tesla. In an embodiment, the magnetic via 116 comprises a material with a saturation flux density between about 1.8 Tesla and about 2.5 Tesla. In various embodiments, the magnetic via 116 may comprise CoFeCu, Ni₃₀Fe₇₀, CoNiFe, Ni₂₀Fe₈₀, FeCoAlO, CoFe, or another material. Thus, the material of the magnetic via 116 is capable of accommodating additional magnetic flux per given volume compared to the material(s) of the upper and lower magnetic layers 114, 108. The magnetic via 116 may include an adhesion layer (not shown) and/or a barrier layer (not shown) and/or other layers of material in addition to the magnetic material.

Together, the upper and lower magnetic layers 114, 108, coil 110, and magnetic via 116 may be considered an integrated inductor. There may be a dielectric material 118 that covers the inductor. Note that while the inductor is illustrated in FIG. 1a as being above the interconnect/ILD layers 106, in some embodiments the lower magnetic layer 108, coil 110, upper magnetic layer 114, and magnetic via 116 may be below some or all of the interconnect/ILD layers 106. In an embodiment, the inductor may operate at a frequency between about 10 MHz and about 500 MHz. In other embodiments, higher or lower frequencies, such as 1-10 MHs or 0.5-1.0 GHz may be used. For lower frequencies, larger sized inductors may be used, while smaller inductors may be used at higher frequencies.

FIG. 1b is similar to FIG. 1a, and illustrates the path 120 of magnetic flux in the magnetic material of inductor of the device 100. As shown, the flux path 120 goes from right to left in the upper magnetic layer 114, down through the magnetic via 116, and from left to right in the lower magnetic layer 108. There is a sharp corner 122 at the bottom of the magnetic via 116 in the illustrated embodiment. The magnetic flux may be more concentrated adjacent this sharp corner 122, so that if the material of the magnetic via 116 were to have the same saturation flux density as the material of the upper and lower magnetic layers 114, 108, it could saturate. By using a material in the magnetic via 116 with a higher saturation flux density, the magnetic via 116 may remain unsaturated, resulting in better inductor performance.

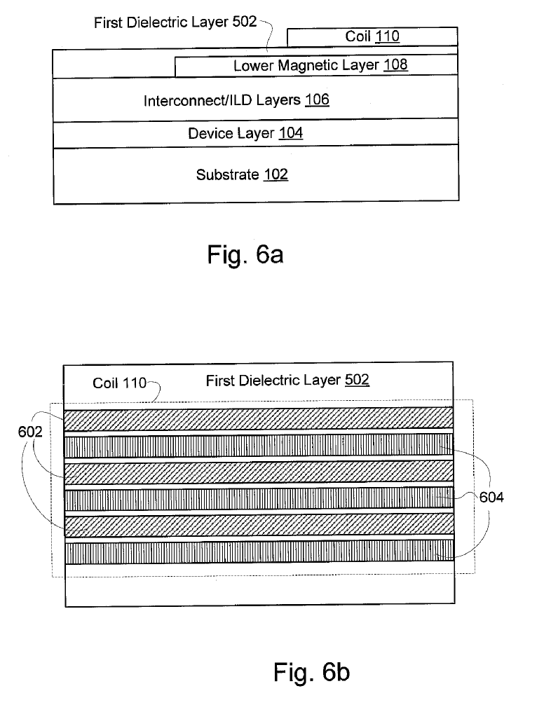

FIGS. 1c and 1d are top views that further illustrates the inductor of FIGS. 1a and 1b to show where the cross sections of those Figures may be taken in an embodiment. FIG. 1c illustrates an embodiment with a “coil” shaped coil 110, and FIG. 1d illustrates an embodiment where the coil 110 is not “coil” shaped, as is described in more detail with respect to FIG. 6b, below. As seen in FIGS. 1c and 1d, the upper magnetic layer 114 maybe on top of the coil 110. FIGS. 1a and 1b show a portion of a cross section of the device 100 taken through line A-A. FIGS. 1a and 1b show a portion of the device 100 taken through the top portion of line A-A, so that the uppermost portion of the coil 110 is shown, along with the upper edge of the upper magnetic layer 114, as it is oriented in FIGS. 1c and 1d.

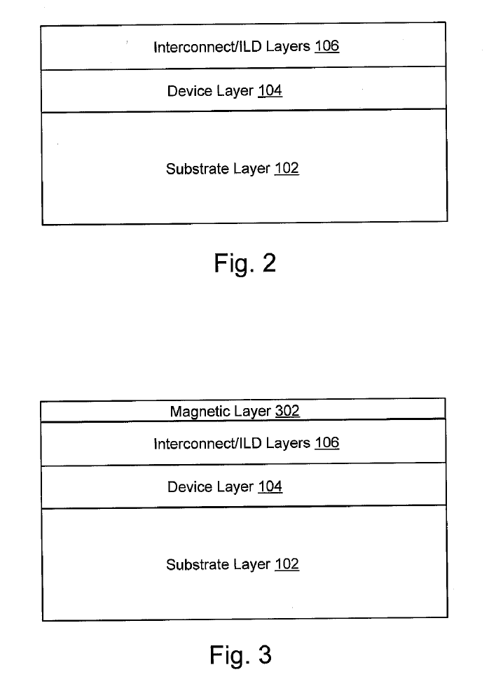

FIGS. 2 through 10 are cross sectional side views that illustrate the formation of the device 100 as described above with respect to FIG. 1, according to one embodiment of the present invention. In other embodiments, the device 100 may be formed in different ways.

FIG. 2 is a cross sectional side view that that illustrates an embodiment with the device layer 104 on the substrate layer 102 and the interconnect/ILD layers 106 on the device layer 104. Any suitable method may be used to form the device layer 104 and interconnect/ILD layers 106.

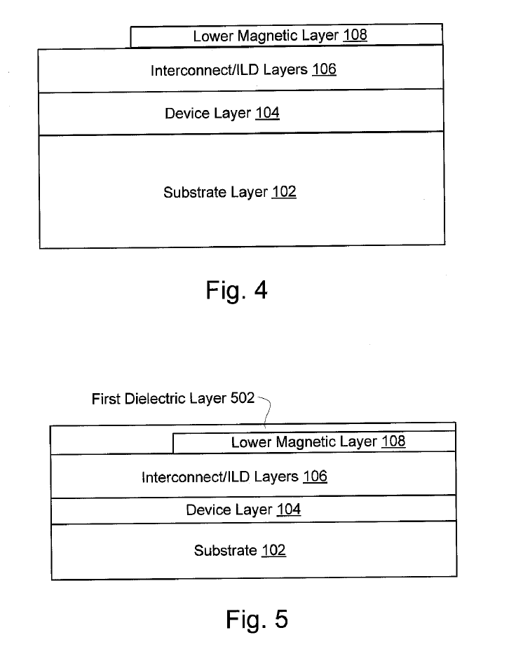

FIG. 3 is a cross sectional side view that that illustrates a blanket magnetic layer 302 formed on the interconnect/ILD layers 106. The magnetic layer 302 may comprise any material or materials suitable for use as the lower magnetic layer 108. Any suitable method may be used to form the blanket magnetic layer 302. FIG. 4 is a cross sectional side view that illustrates the lower magnetic layer 108 formed by patterning the blanket magnetic layer 302, which may be done by any suitable method. FIG. 5 is a cross sectional side view that illustrates a first dielectric layer 502 formed over the patterned lower magnetic layer 108. This first dielectric layer 502 may insulate the coil 110 from the bottom magnetic layer 108 and a portion of it may become part of dielectric material 112, while another portion may become part of dielectric 118.

FIGS. 6a and 6b are a cross sectional view and a top view illustrating the coil 110 formed on the first dielectric layer 502, according to one embodiment of the present invention. For example, a seed layer may be formed, then a mask may cover areas of the seed layer. Conductive material may then be electroplated in the uncovered areas to form the coil 110, followed by removing the mask and etching the portions of the seed layer that had been under the mask. Other methods may be used as well. As seen in the top view of FIG. 6b, in some embodiments the coil 110 may not have a “coiled” shape. In the embodiment illustrated in FIG. 6b, the input “windings” 602 and “output windings” 604 are substantially straight instead of coiled. Thus, the term “coil” as used herein encompasses inductor conductors that are of shapes different than a coil, such as the straight shape pictured in FIG. 6b. The input windings 602 and output windings 604 are alternated so that (except on the outside of the coil 110) each input winding 602 is between two output windings 604, and each output winding 604 is between two input windings 602 in the illustrated embodiment. The coil 110 may also have a “coiled” shape, or another shape in other embodiments.

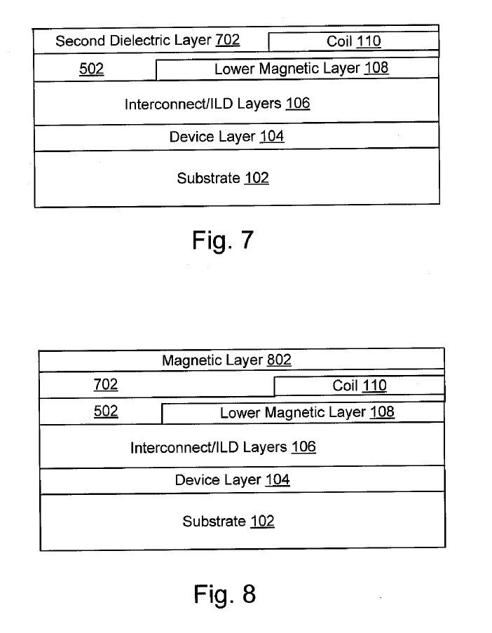

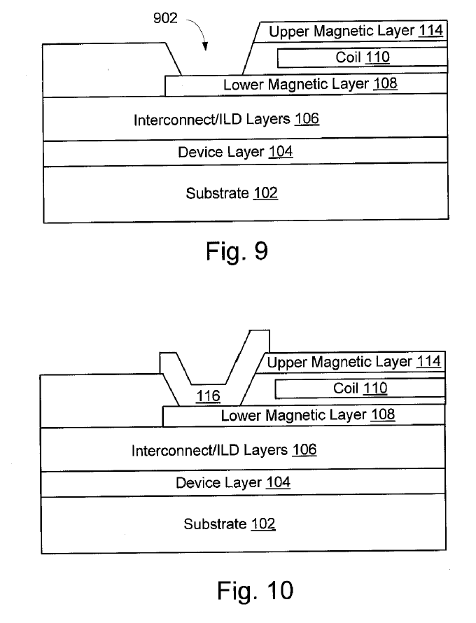

FIG. 7 is a cross sectional side view that that illustrates a second dielectric layer 702 formed over the coil 110. This second dielectric layer 702 may insulate the coil 110 from the top magnetic layer 114 and a portion of it may become part of dielectric material 112, while another portion may become part of dielectric 118. FIG. 8 is a cross sectional side view that that illustrates a blanket magnetic layer 802 formed on the second dielectric layer 702. The magnetic layer 802 may comprise any material or materials suitable for use as the upper magnetic layer 114. Any suitable method may be used to form the blanket magnetic layer 802. FIG. 9 is a cross sectional side view that illustrates a trench 902 formed through the magnetic layer 802 and dielectric layers 502, 702 to the lower magnetic layer 108. Additional portions of the magnetic layer 802 are also removed by any suitable patterning method to result in the upper magnetic layer 114.

FIG. 10 is a cross sectional side view that that illustrates the magnetic via 116 formed in the trench 902. The magnetic via 116 may be formed by depositing a blanket layer of material (or materials), then removing the material(s) in areas other than the trench 902, leaving the magnetic via 116. As stated above, the magnetic via 116 may comprise a material with a higher flux saturation density than that of the upper and lower magnetic layers 114, 108. The magnetic via 116 may also include other layers of material, such as adhesion or barrier layers. Additional dielectric material may be formed on the magnetic via 116, upper magnetic layer 114, and dielectric material already present to result in the device of FIG. 1. This additional dielectric material, plus the remaining portions of the first and second dielectric layers 502, 702 form the dielectric 118 shown in FIG. 1.

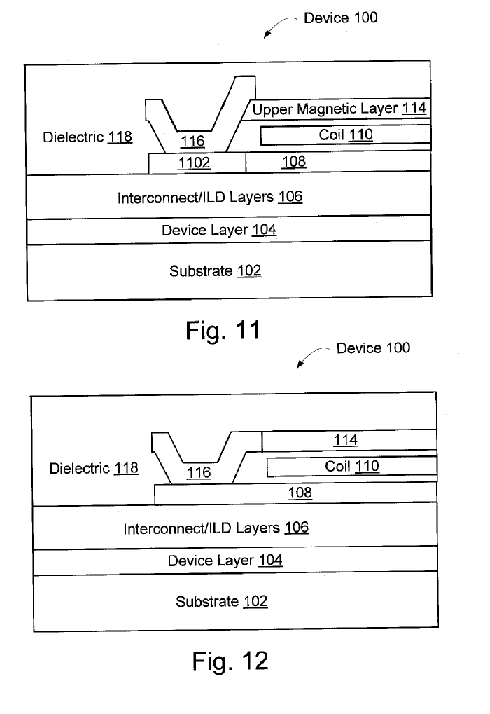

FIG. 11 is a cross sectional side view of another embodiment of the device 100 of FIG. 1. In the embodiment of FIG. 1, the lower magnetic layer 108 does not extend all the way under the magnetic via 116. Rather, there is a section of material 1102 at the same level as the lower magnetic layer 108 that comprises the same higher flux saturation density material as the material of the via 116. The section of material 1102 may be considered part of the magnetic via 116, as it includes the higher magnetic flux saturation density material and part of the path 120 through which magnetic flux travels between the upper and lower magnetic layers 114, 108. The embodiment of FIG. 11 provides for more of the higher magnetic flux saturation density material to be adjacent the sharp corner 122, at which flux density is likely to be higher. Note that various embodiments may lack the sharp corner 122 that is illustrated in the figures, and may have, for example, a magnetic via 116 with vertical sides rather than angled sides, or have other configurations.

FIG. 12 is a cross sectional side view of yet another embodiment of the device 100. In the embodiment of FIG. 12, the trench 902 is formed through the dielectric layers 502, 702 prior to forming the layer of magnetic material 802 from which the upper magnetic layer 114 is patterned. The layer of magnetic material 802 is then formed, with areas of that layer 802 removed to result in the upper magnetic layer 114. The material of the magnetic via 116 may then be deposited. This method of forming the device 100 may result in the tops of the magnetic via 116 and upper magnetic layer 114 being relatively level, as illustrated in FIG. 12.

There are numerous other ways in which to form the device 100 with the magnetic via 116 comprising a material with a higher magnetic saturation flux density than the material of the upper and lower magnetic layers 114, 108 of an inductor. The various layers and structures may be formed by various processes and in different orders, and still fall within the scope of the invention.

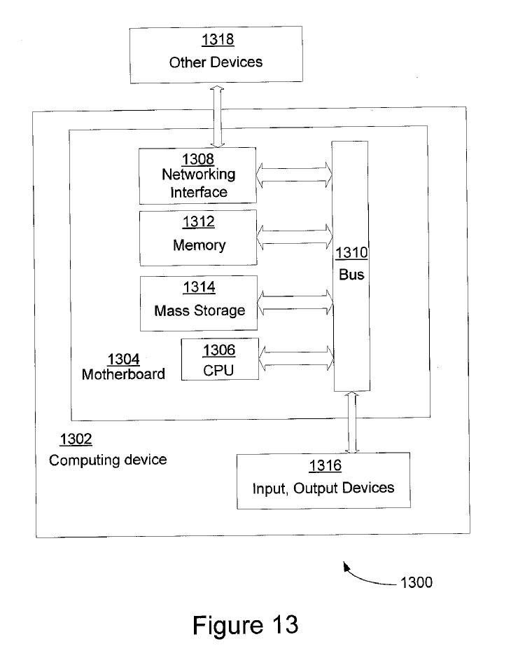

FIG. 13 illustrates a system 1300 in accordance with one embodiment of the present invention. One or more inductors with a magnetic via 116 comprising a material with a higher magnetic saturation flux density than the material of the upper and lower magnetic layers 114, 108 may be included microelectronic dies in the system 1300 of FIG. 13. As illustrated, for the embodiment, system 1300 includes a computing device 1302 for processing data. Computing device 1302 may include a motherboard 1304. Coupled to or part of the motherboard 1304 may be in particular a processor die 1306, and a networking interface 1308 coupled to a bus 1310. A chipset may form part or all of the bus 1310. The processor die 1306 may include one or more processor cores, and one or more of the integrated inductors described herein may also be integrated on the die 1306. The chipset and/or other parts of the system 1300 may include one or more of the integrated inductors described above.

Depending on the applications, system 1300 may include other components, including but are not limited to volatile and non-volatile memory 1312, a graphics processor (integrated with the motherboard 1304 or connected to the motherboard as a separate removable component such as an AGP or PCI-E graphics processor), a digital signal processor, a crypto processor, mass storage 1314 (such as hard disk, compact disk (CD), digital versatile disk (DVD) and so forth), input and/or output devices 1316, and so forth.

In various embodiments, system 1300 may be a personal digital assistant (PDA), a mobile phone, a tablet computing device, a laptop computing device, a desktop computing device, a set-top box, an entertainment control unit, a digital camera, a digital video recorder, a CD player, a DVD player, or other digital device of the like.

The foregoing description of the embodiments of the invention has been presented for the purposes of illustration and description. It is not intended to be exhaustive or to limit the invention to the precise forms disclosed. This description and the claims following include terms, such as left, right, top, bottom, over, under, upper, lower, first, second, etc. that are used for descriptive purposes only and are not to be construed as limiting. For example, terms designating relative vertical position refer to a situation where a device side (or active surface) of a substrate or integrated circuit is the “top” surface of that substrate; the substrate may actually be in any orientation so that a “top” side of a substrate may be lower than the “bottom” side in a standard terrestrial frame of reference and still fall within the meaning of the term “top.” The term “on” as used herein (including in the claims) does not indicate that a first layer “on” a second layer is directly on and in immediate contact with the second layer unless such is specifically stated; there may be a third layer or other structure between the first layer and the second layer on the first layer. The embodiments of a device or article described herein can be manufactured, used, or shipped in a number of positions and orientations. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

I claim:

1. A semiconductor device, comprising:
a substrate;
a device layer on the substrate; and
an integrated inductor, including:
a lower magnetic layer comprising a first magnetic material with a first saturation flux density;
an upper magnetic layer comprising the first magnetic material;
a electrically conductive coil between the upper and lower layers; and
a magnetic via between the lower magnetic layer and the upper magnetic layer, the magnetic via comprising a second magnetic material with a second saturation flux density at least about 30% higher than the first saturation flux density.

2. The device of claim 1, wherein the first magnetic material is selected from a list consisting of Ni₈₀Fe₂₀, CoZrTa, and Ni₄₅Fe₅₅.

3. The device of claim 2, wherein the second magnetic material is selected from a list consisting of CoFeCu, Ni₃₀Fe₇₀, CoNiFe, Ni₂₀Fe₈₀, FeCoAlO, and CoFe.

4. The device of claim 1, wherein the first magnetic material has a saturation flux density between about 1.0 Tesla and about 1.7 Tesla, and the second magnetic material has a saturation flux density between about 1.8 Tesla and about 2.5 Tesla.

5. The device of claim 1, wherein the magnetic via has a top wider than a bottom, and wherein an angle between a side of the magnetic via and an upper surface of the lower magnetic layer is 80 degrees or less from vertical.

6. The device of claim 5, wherein the lower magnetic layer has a first section that comprises the first magnetic material and a second section beneath the magnetic via, the second section comprising the second magnetic material.

7. The device of claim 1, wherein the device layer includes multiple microprocessor cores.

8. A microprocessor die with an integrated voltage regulator, comprising:
a substrate;
a device layer including a plurality of transistors on the substrate;
a plurality of interlayer dielectric layers and layers of electrically conductive traces and vias on the device layer;
a first magnetic layer on the plurality of interlayer dielectric layers and layers of electrically conductive traces and vias;
an electrically conductive coil on the first layer of magnetic material;
a second magnetic layer on the electrically conductive coil;
a magnetic via; and
wherein the first magnetic layer, the second magnetic layer, and the magnetic via form a magnetic pathway, the magnetic pathway including an angle of greater than 280 degrees, and adjacent to the angle is a first magnetic material with a saturation flux density at least 30% greater than the saturation flux density of a second magnetic material elsewhere in the magnetic pathway.

9. The device of claim 8, wherein the magnetic pathway includes an angle of greater than 300 degrees.

10. The device of claim 8, wherein the first magnetic material is selected from a list consisting of CoFeCu, Ni₃₀Fe₇₀, CoNiFe, Ni₂₀Fe₈₀, FeCoAlO, and CoFe.

11. The device of claim 10, wherein the second magnetic material is selected from a list consisting of Ni₈₀Fe₂₀, CoZrTa, and Ni₄₅Fe₅₅.

12. The device of claim 8, wherein the second magnetic material has a saturation flux density between about 1.0 Tesla and about 1.7 Tesla, and the first magnetic material has a saturation flux density between about 1.8 Tesla and about 2.5 Tesla.

13. The device of claim 8, wherein the device layer includes multiple microprocessor cores.

14. The device of claim 8, wherein the magnetic via comprises the first magnetic material.

15. The device of claim 14, wherein the first and second magnetic layers comprise the second magnetic material.

16. The device of claim 8, wherein the magnetic via extends from at least adjacent a level of a top surface of the first magnetic layer to at least a level of a bottom surface of the second magnetic layer.

17. A method to form a semiconductor device, comprising:
forming a device layer on a substrate;
forming a lower magnetic layer comprising a first magnetic material;
forming an electrically conductive coil;
forming an upper magnetic layer comprising the first magnetic material; and
forming a magnetic via comprising a second magnetic material with a saturation flux density at least about 30% higher than a saturation flux density of the first magnetic material.

18. The method of claim 17, wherein forming the device layer comprises forming multiple microprocessor cores.

19. The method of claim 17, wherein the first magnetic material has a saturation flux density between about 1.0 Tesla and about 1.7 Tesla, and the second magnetic material has a saturation flux density between about 1.8 Tesla and about 2.5 Tesla.
